(19) United States
(12) Patent Application Publication
(10) Pub. No.: US 2015/0228549 A1
(43) Pub. Date: Aug. 13, 2015

(54) Method for the Construction of an LED Light Module

(71) Applicant: Hella KGaA Hueck & Co., Lippstadt (DE)

(72) Inventors: Guiseppe Mattina, Lippstadt (DE); Stephan Schröder, Lippstadt (DE)

(21) Appl. No.: 14/618,788

(22) Filed: Feb. 10, 2015

(30) Foreign Application Priority Data
Feb. 13, 2014 (DE) 102014101783.8

(51) Int. Cl. H01L 21/66; H01L 33/62; H01L 33/00; H01L 33/58

(52) U.S. Cl. CPC H01L 22/12; H01L 33/58; H01L 33/62; H01L 33/005; H01L 2933/0033

(57) ABSTRACT

A method for the construction an LED light module, having a printed circuit board, on which at least one LED lamp is accommodated, and having at least one optical element, into which the light generated by the LED lamp can be emitted, wherein the optical element has mounting pins and wherein holes are formed in the printed circuit board, such that the optical element is arranged on the printed circuit board by an insertion of the mounting pins in the holes, wherein the method comprises at least the following steps:
arrangement of at least one LED lamp on a mounting surface of the printed circuit board,
measurement of the position of the LED lamp in the plane of the mounting surface of the printed circuit board,
creation of the holes in the printed circuit board at a position that is dependent on the measured position of the LED lamp in the plane of the mounting surface, and
arrangement of the optical element on the printed circuit board by means of an insertion of the mounting pins in the holes.

### CROSS REFERENCE

This application claims priority to German Application No. 10 2014 101783.8, filed Feb. 13, 2014, which is hereby incorporated by reference.

### FIELD OF TECHNOLOGY

The present invention relates to a method for constructing an LED light module, having a printed circuit board, on which at least one LED lamp is accommodated, and having at least one optical element, into which the light generated by the LED lamp can be emitted, wherein the optical element has mounting pins, and wherein holes are formed in the printed circuit board, such that the optical element is disposed on the printed circuit board by inserting the mounting pins in the holes.

In the present case, an LED light module is understood to be any structural unit that is designed for emitting light, and which can preferably be installed in the housing of a headlamp for a motor vehicle. As a lamp, the LED light module comprises an LED lamp thereby, thus a semiconductor lamp, wherein an LED light module can include one or more LED lamps. A printed circuit board is understood to be, in the present case, any, in particular flat, body, on or in which an LED lamp can be disposed, and in particular, can also be powered by electricity. Thus, the printed circuit board can include any form of a circuitry carrier technology, e.g. an IMS technology, an FPC (flexible printed circuit) technology, an aluminum-based FPC board, a Direct Copper Bonding board, so-called DCBs, a carrier body having a so-called Thick Film technology basis, etc.

### BACKGROUND

DE 10 2007 0034 123 A1 discloses a method for the construction of an LED light module, and a printed circuit board is provided, on which an LED lamp is accommodated, and an optical element in the form of an attachment lens is shown, having mounting sections in the form of pins, by means of which the optical element is mounted on a receiving body formed by a heat sink. The pins, after they have been inserted in respective holes allocated thereto, formed in the heat sink, are subjected to a plastic deformation, by means of which a form-locking connection is created between the optical element and the receiving body. The arrangement of the optical elements occurs after the LED lamps have been disposed on the printed circuit board, which in turn is disposed on the heat sink. If the attachment lens is connected to the heat sink, there is no possibility of re-aligning the optical element in the plane at a right angle to the extension of the pins. This can result in an erroneous positioning of the LED lamp in relation to the optical element, and the erroneous positioning is caused, in particular, by the SMD installation of the LED lamp on the mounting surface of the printed circuit board. The LED lamp, which is designed as an SMD component, is soldered onto the mounting surface of the printed circuit board, by means of which tolerances may form, which lead to an erroneous positioning of the LED lamp in relation to the optical element, which is disposed on the heat sink in a rigid position that cannot be changed. In particular, further tolerances my arise in the extension plane of the printed circuit board, as a result, for example, of the connection between the printed circuit board and the heat sink. Lastly, this can result in optical aberrations, which should always be avoided.

DE 10 2009 049 016 A1 discloses another structure for an LED light module, and an optical element in the form of an attachment lens is attached to a printed circuit board, wherein, in turn, an attachment dome is provided, which is inserted through a hole in the printed circuit board. Alternatively to a known clinch sealing of the dome on the back surface of the printed circuit board, it is proposed therein that an interlocking, by means of a sheet metal element, of a sheet metal edge of the sheet metal element is to be created in the outer surface of the attachment dome for the attachment lens. An adjustment of the attachment lens in relation to an LED lamp that is accommodated on the printed circuit board is also not possible with the structure of this LED light module.

### SUMMARY OF THE INVENTION

The object of the invention is to further develop a method for the construction of an LED light module, having a high positioning precision for the LED lamp on a printed circuit board in relation to at least one optical element.

The inventive method includes at least the following steps: arrangement of at least one LED lamp on a mounting surface of the printed circuit board, measurement of the position of the LED lamp in the plane of the mounting surface of the printed circuit board, formation of holes in the printed circuit board, having a position that is dependent on the measured position of the LED lamp in the plane of the mounting surface, and the arrangement of the optical element on the printed circuit board by inserting the mounting pins thereof in the holes.

By means of the method features in accordance with the present invention, the advantage is obtained that the optical element can be very precisely aligned in relation to the LED lamps, independently of occurring tolerances. By means of the preceding arrangement of LED lamp on the printed circuit board, in which deviations in the position of the LED lamp in the plane of the mounting surface can occur, these deviations can be detected, in addition to other deviations, and two holes for each LED lamp, for example, can be created in relation to the actual position of the LED lamp in the plane of the mounting surface.

Computing operations can be carried out between the procedure for measuring the position of the LED lamp and the creation of the hole, or the holes, respectively, in order, for example, to adjust a tool for creating the holes to the actual position of the respective LED lamp.

By way of example, a reference position can be defined by the actual position of an LED lamp, based on which, for example, two holes can be created.

Advantageously, the creation of the holes in the printed circuit board can be carried out by a machining, in particular by a milling, or by a drilling.

It is further advantageous that the LED lamp can have a light exit surface, wherein the measurement of the position of the LED lamp in the plane of the mounting surface is carried out on the light exit surface. By way of example, LED lamps are known, having a light exit surface of only 1 mm×1 mm, such that a deviation in the position of the LED lamp on the mounting surface of the printed circuit board, resulting from the soldering procedure, of only 0.5 mm in the mounting surface in relation to the optical element can significantly impair the function of the LED light module. By way of example, the optical element can have a focus, which should lie as close as possible to the center of the light exit surface. If the position of the LED lamp in relation to the optical element deviates, for example, in an X-direction, and a Y-direction running at a right angle thereto, by 50% in each case from the size of the light exit surface, then only a quarter of the light exit surface still remains in the focus of the optical element.

The LED lamp can be designed as an SMD component (Surface Mounted Device), which is soldered onto the mounting surface of the printed circuit board in a reflow procedure, for example. During this procedure, the LED lamp may shift in position, such that the position of an LED obtained when the solder has cooled can strongly deviate from a target position to an unacceptable extent.

According to one advantageous embodiment of the method, the measurement of the position can be executed by means of an optical measuring means, in particular by means of a camera. The method step of measuring the position occurs, in particular, without contact regarding the LED lamp, and in particular, the position of the light exit surface in the mounting plane can be determined.

The method for constructing the LED light module can also be used when numerous LED lamps are to be accommodated on the printed circuit board. In doing so, the measurement of at least one position of an LED lamp in an X,Y plane and/or the elevation thereof, can occur according to a predefined photometric quantifier. By way of example, the light module can have a central LED lamp, on which the determination of the position is carried out. In particular, LED lamps having a critical photometric function can be prioritized during the tolerance compensation.

To further advantage, a suction device can be provided, wherein the creation of the holes in the printed circuit board is carried out while, at the same time, a vacuuming off of substances, such as shavings, that result from the creation thereof, can be carried out. If, for example, the creation of the holes occurs by means of a milling procedure, or a drilling procedure, then the resulting shavings can be vacuumed off by means of the suction device. The suction device can, for example, have a suction tube, which encompassed the machining tool, e.g. a milling cutter. If a vacuum is generated in the suction tube, then shavings that are generated during the creation of the hole can be removed by means of the suction tube.

According to an advantageous embodiment variation of the method, first, numerous LED lamps can be disposed on a single printed circuit board, and, by way of example, the numerous LED lamps can be pre-positioned, and subsequently soldered thereto by means of a reflow process. Subsequently a respective measurement of the position of the LED lamp in the plane of the mounting surface can be carried out. Following this, holes are formed, wherein each LED lamp is allocated two or more holes, for example, and the position of the holes depends on the measured position of the respective LED lamp in the plane of the mounting surface. Lastly, the method is completed with the arrangement of optical elements on the printed circuit board, wherein each LED lamp is allocated to an optical element. The described method can, accordingly, comprise an arrangement of the LED lamp, the measurement, and the creation of the holes for each individual LED, sequentially, for example.

According to a further development of the method and depending on the embodiment of the LED light module, the optical element can be designed such that it extends over numerous LED lamps, such that numerous LED lamps, disposed in a row, for example, emit light into the optical element. It ,may be provided thereby that the measurement of the positions of at least two LED lamps in the plane of the mounting surface is carried out, and subsequently, the optical element is attached to the printed circuit board, in that mounting pins on the element are inserted in holes, wherein the holes can exhibit a position, independently of one another, that is determined by the measurement of the various LED lamps.

Although the position of the respective holes is determined thereby, not based on each position of the LED lamps, it is still possible to determine, however, that with a placement of the LED lamp, in particular as an SMD component, the position of the LED lamps in relation to one another exhibit a lesser deviation than the overall position of the LED lamps in relation to the dimensions of the printed circuit board. By means of this method, the positional precision of a special optical element, into which the light from numerous LED lamps is emitted, in relation to the LED lamps can be improved by approx. 50%, because the positions of the LED lamps in relation to one another exhibit smaller tolerances than the overall positions of the LED lamps in relation to otherwise arbitrarily created holes.

The present invention also relates to an LED light module, having a printed circuit board, on which at least one LED lamp is accommodated, and having at least one optical element, into which the light generated by the LED lamp can be emitted, wherein the optical element has mounting pins, and wherein holes are formed in the printed circuit board, and wherein the optical element is disposed on the printed circuit board by inserting the mounting pins in the holes. The inventive LED light module has holes thereby, having a position aligned with the at least one LED lamp, wherein the holes exhibit a form that is generated by machining.

The holes can be round or elongated thereby, wherein round holes are preferably created with a drilling tool, and elongated holes can be created with a milling tool. An LED lamp can be allocated one round hole and one elongated hole thereby, for example. As a result, the advantage is obtained that tolerances between the mounting pins on the optical element and the positions of the holes during the installation of the optical element on the printed circuit board do not create a problem, and the optical element can, for example, be positioned in the X,Y plane by means of the round hole, and the second mounting pin can be received in the elongated hole, by means of which the position of the optical element over the LED lamp is ultimately defined.

### BRIEF DESCRIPTION OF THE DRAWINGS

Reference is now made more particularly to the drawings, which illustrate the best presently known mode of carrying out the invention and wherein similar reference characters indicate the same parts throughout the views.

FIG. 1 is a schematic sequence of numerous method steps according to the features of the present invention.

FIG. 2 is a schematic view of a printed circuit board on which, by way of example, seven LED lamps are disposed.

FIG. 3 is the printed circuit board with the LED lamps according to FIG. 2, wherein the positions of the LED lamps are measured in the next method step, and according to a corresponding calculation, holes are formed in the printed circuit board.

FIG. 4 is a side view of the printed circuit board with the optical elements that are to be placed on the mounting surface.

FIG. 5 is the assembled arrangement of the optical elements on the printed circuit board.

FIG. 6 is an embodiment variation of the invention, wherein the optical element is designed such that it extends over all of the shown LED lamps.

FIG. 7 is a side view of the arrangement of the optical elements according to FIG. 6.

### DETAILED DESCRIPTION OF THE DRAWINGS

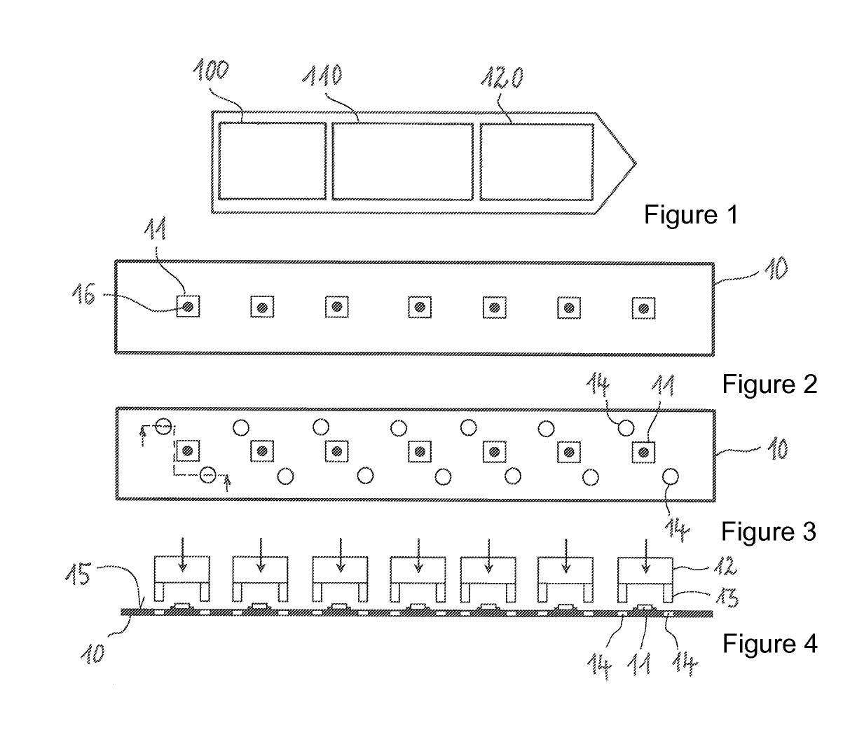

FIG. 1 shows a schematic view of the sequence of the inventive method for constructing an LED light module. The method comprises, as method steps essential to the invention, first, the arrangement 100 of an LED lamp on a printed circuit board, wherein the method step for arranging 100 can comprise at least a soldering procedure, for example, and the LED lamp can be designed as a SMD component that is to be soldered onto the mounting surface of the printed circuit board.

The measurement 110 of the position of the LED lamp in an X,Y plane in the mounting surface of the printed circuit board is provided as a further method step. The method step comprising the measurement 110 can, for example, be carried out by an optical measuring means, in particular by means of a camera. Subsequently, the method step for creating 120 holes in the printed circuit board occurs.

The creation 120 of the holes can, for example, occur by means of a milling procedure, using a machining tool. If an optical element is to subsequently be placed on the printed circuit board by inserting mounting pins located on the optical element into the holes, then there is the advantage that the optical element is very precisely oriented with respect to the position of the LED lamp, in particular with respect to a light exit surface of the LED lamp.

The inventive method can be a part of an entire production and assembly method for manufacturing an LED light module, wherein the listed method steps, essential to the invention, can be integrated in a larger number of individual, successive method steps.

FIG. 2 shows a schematic view of a printed circuit board 10, on which, by way of example, seven LED lamps 11 are arranged. The LED lamps 11 are disposed in a common row on the printed circuit board 10 thereby. Each of the LED lamps 11 has a light exit surface 16, by means of which the light from the LED lamps is emitted. Thus, FIG. 2 shows an LED light module having a printed circuit board 10 and a number of LED lamps 11, which are already placed on the mounting surface 15 of the printed circuit board 10 in accordance with the first method step 100.

FIG. 3 shows the printed circuit board 10 with the LED lamps 11 according to FIG. 2, wherein the position of the LED lamps 11 is measured in the next method step 110, and according to a corresponding calculation, the positions of the holes 14 that are to be formed in the printed circuit board 10 are calculated. In each case, two holes 14 are shown, which are allocated to a respective LED lamp 11. The number, of two holes 14 for each LED lamp, is merely exemplary, and more than two holes 14 for each LED lamp 11, in order to arrange a corresponding optical element over the LED lamps 11 allocated thereto, can also be provided. In particular, all of the holes 14 are simply shown with a round shape, and each LED lamp 11 can also have a round and an elongated hole 14 allocated to it according to an advantageous embodiment variation.

FIG. 4 shows a side view of the printed circuit board 10 with the optical elements 12 that are to be placed on the mounting surface 15, wherein each LED lamp 11 is allocated to an optical element 12. A respective arrow indicates a joining direction for the optical element 12, such that mounting pins 13, which are attached to the optical elements 12, can be inserted in the holes 14 in the printed circuit board 10. The depiction shows two holes 14 allocated to each LED lamp 11, which are shown in a sectional view, cut in accordance with the cut line indicated in FIG. 3.

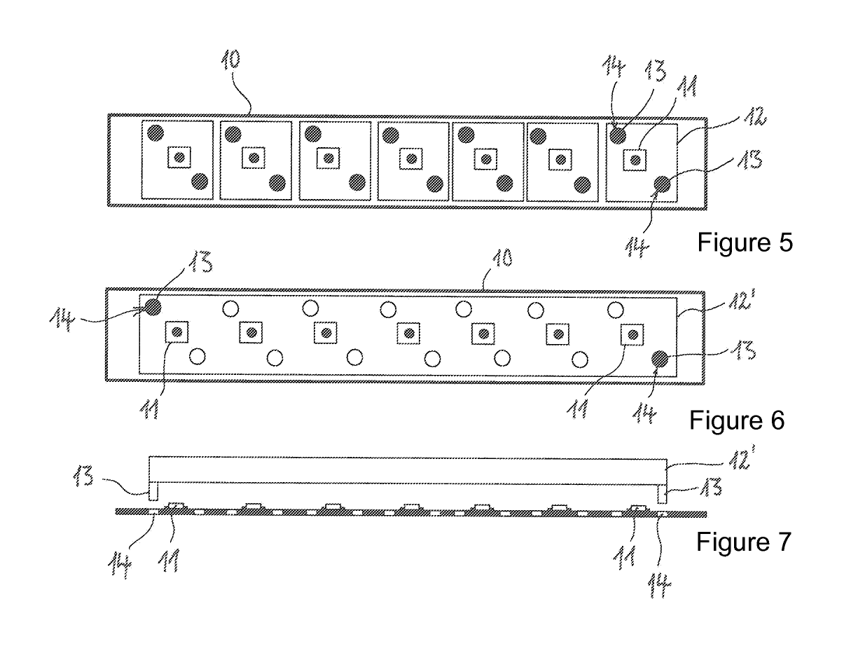

FIG. 5 shows the joined assembly of the optical element 12 on the printed circuit board 10, such that the mounting pins 13 of the optical element 12 are inserted in each hole 14. As a result, the optical elements 12 are positioned exactly over the LED lamps 11, wherein the seven LED lamps 11 are individually allocated to respective optical elements 12. The optical elements 12 can, for example, faun reflectors or lenses, in order to obtain a shaping of the respective light emitted by the LED lamps 11.

FIG. 6 shows an embodiment variation of the invention, wherein the optical element 12′ is designed such that it extends over all of the shown LED lamps 11. In order to arrange the optical element 12′ on the printed circuit board 10, two mounting pins 13, by way of example, are inserted in the holes 14 allocated thereto, which are in turn allocated to various LED lamps 11, wherein four mounting pins 13 can also be provided for a corresponding stability of the optical element 12′ in its arrangement on the printed circuit board 10, which, accordingly, can be inserted in four holes 13 allocated thereto.

FIG. 7 shows a side view of the arrangement of the optical element 12′ according to FIG. 6, and the advantage is, despite the allocation of various holes 14 to the mounting pins 13 of the optical element 12′, an improved positional precision of the LED lamps 11 in relation to the optical element 12′. The advantage is obtained, in particular, in that, when the LED lamps are placed on the printed circuit board 10, the position of the LED lamps 11 in relation to one another is more precise than the overall position of the LED lamps 11 on the printed circuit board 10. If the holes 14 are formed in the printed circuit board 10 independently of a measurement of the positions of the LED lamps 11, then the position of the optical element 12′ is more strongly subjected to tolerances than in the illustrated assembly.

The invention is not limited in its embodiment to the preferred embodiment example given above. On the contrary, a number of variations are conceivable, which may also make use of the depicted solution with fundamentally different embodiments. All of the features and/or advantages that can be derived from the claims, the description, or the drawings, including constructive details, spatial arrangements and method steps, may be essential, both in and of themselves, as well as in the various combinations thereof.

### LIST OF REFERENCE SYMBOLS

10 printed circuit board
11 LED lamp
12 optical element
12′ optical element
13 mounting pins
14 hole
15 mounting surface
16 light exit surface
100 arrangement method step
110 measurement method step
120 production method step

1. A method for the construction of an LED light module, having a printed circuit board, on which at least one LED lamp is accommodated, and having at least one optical element, into which the light that can be generated by the LED lamp can be emitted, wherein the optical element has mounting pins and wherein holes are formed in the printed circuit board, such that the optical element is disposed on the printed circuit board by an insertion of the mounting pins in the holes, wherein the method comprises:
arranging at least one LED lamp on a mounting surface on the printed circuit board,
measuring a position of the LED lamp in a plane of the mounting surface on the printed circuit board,
creating the holes in the printed circuit board at a position that is dependent on the measured position of the LED lamp in the plane of the mounting surface, and
arranging optical element on the printed circuit board by inserting the mounting pins in the holes.

2. The method according to claim 1, wherein the creation of the holes is executed by at least one of milling and drilling.

3. The method according to claim 1 wherein the LED lamp has a light exit surface, wherein the measurement of the position of the LED lamp in the plane of the mounting surface is carried out on the light exit surface.

4. The method according to claim 1 wherein the measurement of the position is executed by means of a camera.

5. The method according to claim 1 wherein:
numerous LED lamps are disposed on the printed circuit board,
a respective measurement of respective positions of the LED lamps in the plane of the mounting surface is carried out,
holes allocated to each LED lamp are formed at a position that is dependent on the measured position of each respective LED lamp in the plane of the mounting surface, and
optical elements allocated to each LED lamp are disposed on the printed circuit board.

6. The method according to claim 1 wherein the optical element is designed such that it extends over numerous LED lamps, and in that numerous LED lamps emit light into the optical element,
wherein the measurement of the position of at least two LED lamps in the plane of the mounting surface is carried out, and
wherein the mounting pins of the optical element are inserted in holes that have a position determined by the measurement of the various LED lamps.

7. An LED light module comprising:
a printed circuit board on which an LED lamp is accommodated, said printed circuit board including holes formed therein;
at least one optical element, into which the light generated by the LED lamps can be emitted, said optical element including mounting pins, and
wherein the optical element is disposed on the printed circuit board by inserting the mounting pins in the holes,
wherein the holes exhibit a position that is aligned with the LED lamps,
wherein the holes have a design that is generated by a machining.

8. The LED light module according to claim 7, wherein that the holes are round or elongated, wherein an LED lamp is allocated one hole with a circular form and one hole with an elongated form.

9. The LED light module according to claim 7 manufactured via the method according to claim 2.
